(19) United States
(12) Patent Application Publication
(10) Pub. No.: US 2010/0107034 A1
(43) Pub. Date: Apr. 29, 2010

(54) INFORMATION PROCESSING DEVICE, PROGRAM AND RECORDING MEDIUM

(75) Inventors: Emi Tsurukiri, Tokyo (JP); Hiroshi Takekawa, Tokyo (JP); Hayashi Ito, Chiba (JP)

Correspondence Address: PEARNE & GORDON LLP, 1801 EAST 9TH STREET, SUITE 1200, CLEVELAND, OH, 44114-3108, US

(73) Assignee: PANASONIC CORPORATION, Osaka (JP)

(21) Appl. No.: 12/530,123

(22) PCT Filed: Mar. 7, 2008
(86) PCT No.: PCT/JP2008/000494

§ 371 Date: Sep. 4, 2009

(30) Foreign Application Priority Data
Mar. 9, 2007 (JP) 2007-060043

(51) Int. Cl. H03M 13/03; G06F 11/08

(52) U.S. Cl. 714/752; 714/E11.03

(57) ABSTRACT

The present invention intends to hold safely string information such as secret information, or the like, and also to lessen user's burden of storing the information in connection to the string information. In registering the secret information, a coding section 16 synthesizes input correct secret information SD and individual characteristic information under a predetermined rule, and produces a code word S16. A check symbol for error correction is produced in the course of the coding of the coding section 16, and this check symbol is stored in a storing section 20. In reproducing the secret information, an error correcting section 22 applies an error correcting process using the check symbol stored in the storing section 20 to a code word, which is produced by the coding section 16 based on the input secret information SD and the individual characteristic information, as the object. Accordingly, the correct secret information is reproduced.

### TECHNICAL FIELD

The present invention relates to the technique to process effectively information as authentication data needed when a particular service is provided to a user of an information processing terminal, or the like.

### BACKGROUND ART

Normally, when a particular service is provided to a user through an information processing terminal, secret information that the user registered in advance (for example, an account, a password, or the like) is demanded to check user's authenticity. However, in a situation that a plurality of services that the user can utilize are present, when the user forgets the secret information for a part of services, such user cannot receive the provision of a part of services. Therefore, such a secret information reproducing device is disclosed that, even though the user forgets a part of secret information out of plural pieces of secret information, a part of secret information can be reproduced by using the error correcting technology (see Patent Literature 1).

According to the secret information reproducing device disclosed in Patent Literature 1, when the secret information except a part of secret information that the user forgot (referred to as “target secret information” hereinafter) out of plural pieces of secret information is input correctly, the target secret information can be reproduced adequately by using the error correcting technology. Also, this secret information reproducing device stores not the secret information itself but only a check symbol used when plural pieces of secret information should be converted into the code word, and therefore has a high confidentiality.

### Patent Literature 1: JP-A-11-252185 (Pages 5, 6)

### DISCLOSURE OF THE INVENTION

### Problems that the Invention is to Solve

However, in the secret information reproducing device disclosed in Patent Literature 1, such a situation may happen that, when the secret information except a part of secret information that the user forgot is not correctly input, the target secret information cannot be reproduced correctly. In other words, the user must store precisely all of secret information except the target secret information in response to the error correcting capability to be set. This respect imposes a burden on the user.

In view of the above problem, it is an object of the present invention to provide an information processing device, a program, and a recording medium, capable of holding safely string information and also lessening user's burden of storing information about the string information and correcting an inputting error.

### Means for Solving the Problems

A first aspect of the present invention provides an information processing device, which is equipped with an information inputting section, an information acquiring section, a coding section, a storing section, and an error correcting section.

The information inputting section inputs string information in response to a user's operation. The information acquiring section acquires individual characteristic information of a user based on the user's operation. The coding section produces a first code word, which is a cord word in which a correct first string information being input by the information inputting section and the individual characteristic information are synthesized under a predetermined rule, in registering the string information. The storing section stores a check symbol for error correction being produced based on the first code word after the string information is registered. At this time, the first string information itself is erased, and thus the correct first string information is protected substantially safety from the other persons.

The error correcting section applies the error correction using the check symbol stored in the storing section to a second cord word, which is produced by the coding section based on second string information being input by the information inputting section and the individual characteristic information, when the string information is reproduced. Accordingly, the correct first string information can be reproduced. Here, the string information in the invention of this application contains not only the normal string information (containing alphanumeric characters, kana and kanji characters, symbols, etc.) but also information of signal trains.

A second aspect of the present invention provides a program of causing a computer to execute procedures in registering string information and procedures in reproducing the string information.

The procedures in registering string information includes a procedure of inputting correct first string information in response to a user's operation, a procedure of acquiring first individual characteristic information of a user based on an input of the first string information, a procedure of synthesizing the first string information and the first individual characteristic information under a predetermined rule, and producing a first code word, and a procedure of erasing the first string information, and storing a check symbol obtained in a course of production of the first code word.

The procedures in reproducing the string information includes a procedure of inputting second string information in response to a user's operation, a procedure of acquiring second individual characteristic information of the user based on an input of the second string information, a procedure of synthesizing the second string information and the second individual characteristic information under the predetermined rule, and producing a second code word, and a procedure of applying an error correction using the stored check symbol to the second code word as an object.

A third aspect of the present invention provides a computer-readable recording medium for storing the program.

### ADVANTAGES OF THE INVENTION

According to the present invention, the string information can be held safely, and also the user's burden of storing the information about the string information and correcting the inputting error can be lessened.

### BRIEF DESCRIPTION OF THE DRAWINGS

FIG. 1 A block diagram showing a configuration of a secret information processing device of a first embodiment of the present invention.

FIG. 2 A flowchart showing a process of acquiring individual characteristic information in the secret information processing device of the first embodiment.

FIGS. 3A to 3C Views showing an example of individual characteristic information.

FIG. 4 A flowchart showing a process in registering secret information in the secret information processing device of the first embodiment.

FIG. 5 A sequence diagram showing a concrete example of data production, in the process in registering the secret information in the secret information processing device of the first embodiment.

FIG. 6 A flowchart showing a process in reproducing the secret information in the secret information processing device of the first embodiment.

FIG. 7 A sequence diagram showing a concrete example of data production, in the process in reproducing the secret information in the secret information processing device of the first embodiment.

FIG. 8 A block diagram showing a configuration of a secret information processing device of a second embodiment of the present invention.

FIG. 9 A flowchart showing a process of reproducing the secret information in the secret information processing device of the second embodiment.

FIG. 10 A flowchart showing a process of verifying the secret information in the secret information processing device of the second embodiment.

FIG. 11 A flowchart showing a process of reproducing the secret information containing another example of a process of verifying the secret information.

FIG. 12 A flowchart showing a process of reproducing the secret information containing still another example of a process of verifying the secret information.

FIG. 13 A flowchart showing a process of reproducing the secret information containing yet still another example of a process of verifying the secret information.

FIG. 14 A flowchart showing a process of reproducing the secret information containing further example of a process of verifying the secret information.

FIG. 15 A block diagram showing a configuration when the secret information processing device of each embodiment is installed into a mobile terminal.

FIG. 16 A block diagram showing a configuration when respective sections of the secret information processing device of each embodiment are separated into a mobile terminal and a card type module and are installed.

### DESCRIPTION OF REFERENCE NUMERALS

1, 2 secret information processing device
3, 4 mobile terminal
5 card type module
10 user interface
12 displaying section
14 data processing section
16 coding section
20 storing section
22 error correcting section
24 verifying section
26 communicating section
800 network
900 server

### BEST MODE FOR CARRYING OUT THE INVENTION

### First Embodiment

A first embodiment of a secret information processing device of the present invention will be explained hereinafter.

The secret information processing device of the present embodiment is the system used to process the secret information. As the typical application in use, such secret information processing device is incorporated into an information processing terminal of a computer, a mobile terminal, or the like. The “secret information” is the data that is also called so-called account, password, or secure code, and is authentication data needed when a particular service is provided to a user. As an example, the account, the password, or the like, which is input by the user to log in the web site, is the secret information in the information processing terminal. Also, personal information such as residence, contact address, and the like are the secret information in the information processing terminal.

In this case, in such a situation that a particular service is not provided to the user from the external equipment via communication, there is no necessity that the secret information processing device or the information processing terminal into which the secret information processing device is incorporated should be equipped with a communicating function.

Here, in the present embodiment, explanation will be made by taking the processing system used to process the secret information as an example, but the present invention is not limited to this example. The present invention is adaptable to the information terminal that employs string information containing alphanumeric characters, kana and kanji characters, symbols, etc. and signal trains as an input object.

The secret information processing device of the present embodiment intends to hold the secret information safely and reduce user's burden of storing the information relating to the secret information. In particular, the secret information processing device of the present embodiment protects the secret information safely from the “fake” when the regular user forgot the correct secret information that is needed to accept the provision of the particular service. Also, the secret information processing device enables the user to reproduce the correct secret information in such a way that the regular user is not compelled to store the information relating to the correct secret information.

More concretely, the secret information processing device of the present embodiment is also applicable to the secret information such as account, password, and the like, and the proper information such as residence, URL, and the like. Also, the secret information processing device of the present embodiment can lessen the user's burden by correcting the string information, which contains partially an error caused due to vague memory, inputting error, or the like, to the right string.

### [Configuration of Secret Information Processing Device 1]

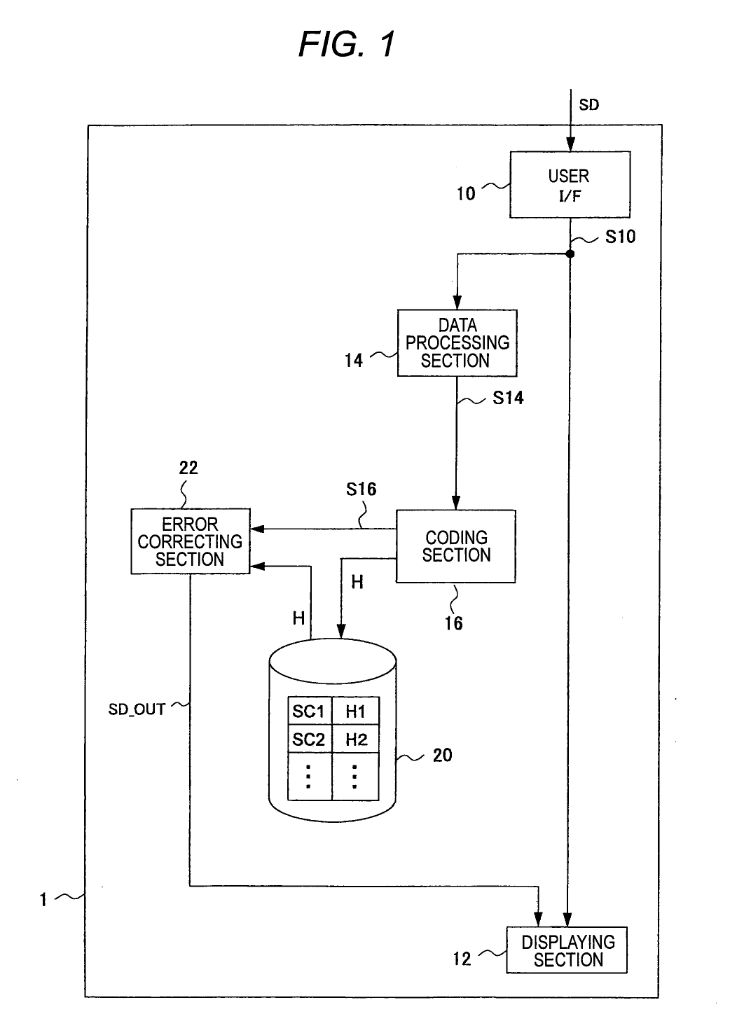

A configuration of a secret information processing device of a first embodiment of the present invention will be explained with reference to FIG. 1 hereunder. FIG. 1 is a block diagram showing a configuration of a secret information processing device 1 of the present embodiment.

As shown in FIG. 1, the secret information processing device 1 is equipped with a user interface (User I/F) 10, a displaying section 12, a data processing section 14, a coding section 16, a storing section 20, and an error correcting section 22. Also, the secret information processing device 1 includes a microcomputer 1 (not shown) exercises data control and timing control between respective sections in the secret information processing device 1.

The user interface 10 (information inputting section) accepts secret information SD as the string, which is input directly from the external equipment or is acquired via another inputting means, in connection with a corresponding service code. The service code is data that is obtained by coding the service that is provided to the user.

The displaying section 12 contains a display panel that is composed of a liquid crystal element or an organic EL element, and causes the display panel to display the string that is input through the user interface 10. In particular, the displaying section 12 of the present embodiment displays the secret information SD as the string, which is input through the user interface 10, or secret information SD_OUT as the string, which is reproduced by the error correcting section 22, on a screen, and thus functions as a man-machine interface when the particular service is provided to the user.

The data processing section 14 (information acquiring section) acquires the individual characteristic information of the user who is going to input the secret information SD, based on string data S10 (=secret information SD) as the output of the secret information SD. This individual characteristic information is the peculiar data produced due to the attributes of individual users. In the present embodiment, in view of such a respect that the string inputting patterns being input through the inputting means such as a keyboard or the like, for example, are different every user, the data processing section 14 acquires an input interval between respective strings of the secret information SD as the individual characteristic information.

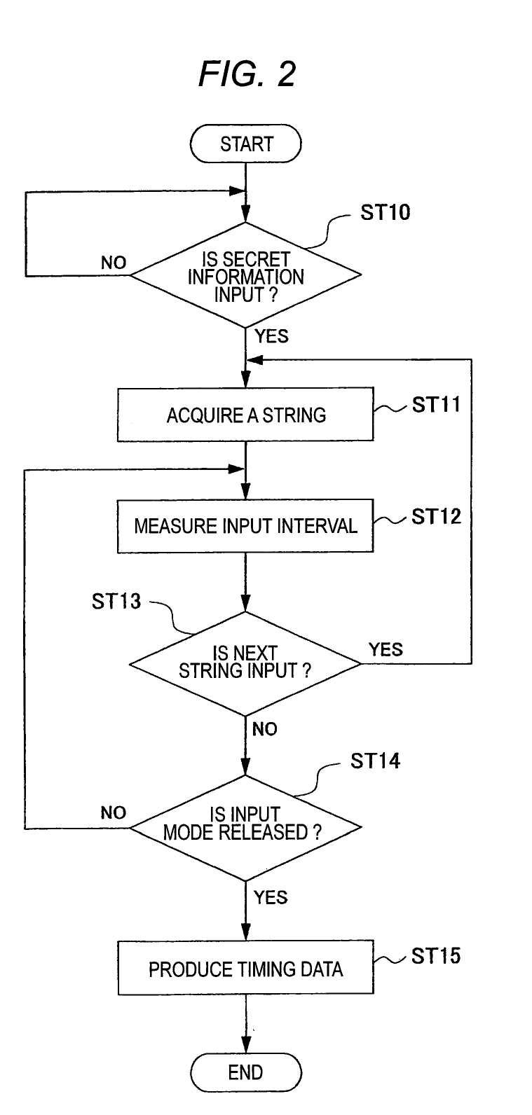

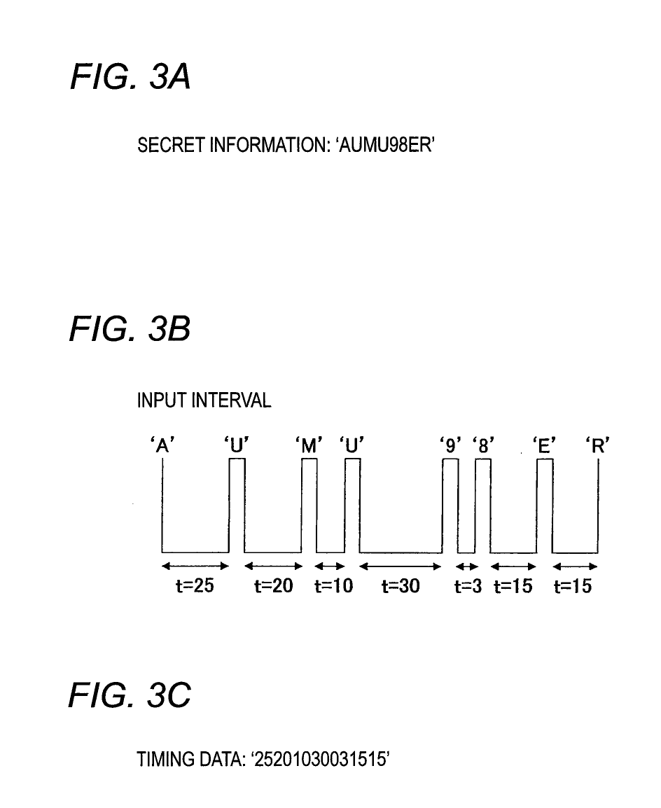

A concrete method of acquiring the individual characteristic information by the data processing section 14 will be explained with reference to FIG. 2 and FIGS. 3A to 3C hereunder. FIG. 2 is a flowchart showing a process of acquiring the individual characteristic information in the data processing section 14. FIGS. 3A to 3C are views showing an example of the individual characteristic information.

First, when the secret information is input (step ST10), the data processing section 14 acquires sequentially respective strings contained in the secret information (step ST11). When the data processing section 14 receives one string, a timer (not shown) in the secret information processing device 1 is operated and starts to measure an input interval between the strings (step ST12). Then, if the next string is input (YES in step ST13), the data processing section 14 acquires that string (step ST11), and also terminates the measurement of the input interval between the string being input precedingly and the string being input this time (step ST12).

The data processing section 14 applies the processes in step ST11 to step ST13 repeatedly to respective strings of the input secret information. If the data processing section 14 determines that an input mode is released, based on the input of particular data (e.g., a return key, or the like) indicating that the input of the secret information is ended (YES in step ST14), such data processing section 14 produces timing data (step ST15). Then, the process is ended.

As shown in FIGS. 3A to 3C, for example, the data processing section 14 receives the secret information ‘AUMU98ER’ (FIG. 3A), and acquires input intervals (FIG. 3B) between the strings in response to this input secret information. Then, the data processing section 14 acquires timing data ‘25201030031515’ (FIG. 3C) as the individual characteristic information concerning the acquired input interval, by combining the input intervals between the strings in series, for example. This method of producing this timing data shows merely an example, and other method may be employed if the method can get the data under a predetermined rule that is detected based on the input intervals between the strings. In this case, even when the secret information is input by the same user, a variation arises in the input interval between the strings. Therefore, it is preferable that, in order to acquire adequately the private attribute, the input interval should be data-processed in view of such variation.

The data processing section 14 produces an information word by synthesizing the secret information SD and the individual characteristic information. As the method of synthesizing the secret information SD and the individual characteristic information to produces the information word, any method may be employed if the information can be separated again after the synthesis (i.e., the secret information SD and the individual characteristic information can be reproduced separately). As the synthesizing method, for example, the method of synthesizing simply the secret information SD and the individual characteristic information in order, the method of combining alternately respective strings of the secret information SD and the individual characteristic information, the method of digitizing the secret information SD and the individual characteristic information under a predetermined rule and calculating them respectively, and the like may be considered.

The coding section 16 produces the code word by coding the information word S14 produced by the data processing section 14 by using a predetermined producing polynomial. As the coding method, any coding method may be employed if such coding method can correct an error. In the present embodiment, the Reed-Solomon (RS) code, e.g., RS (255, 247;4), is employed as the publicly coding method that can correct the error. In this case, the coding section 16 produces the 247-byte information word by supplementing the data into the information word S14 such that the coding can be applied to the information word by this RS (255, 247;4). As a simply mode, this data supplement is executed by padding the 232-byte ‘0’ to the tail of the 15-byte information word S14, for example, such that the information word prior to the coding has 247 byte. Here, of course the data used in the padding (referred to as “padding data” hereinafter) is not limited ‘0’.

The coding section 16 applies the RS coding to the 247-byte information word. In the course of this coding, the check symbol H is produced in a previously set error correcting capability.

The storing section 20 stores the check symbol produced by the coding section 16 (in FIG. 1, H1, H2, . . . ) to correlate with the service code (in FIG. 1, SC1, SC2, . . . ). Also, the storing section 20 does not store the string data S10 (=secret information SD) that forms the basis in producing this check symbol after the check symbol is produced once by the coding section 16 at a time of registration. That is, the string data S10 that forms the basis in producing the check symbol is deleted after the check symbol is produced.

The error correcting section 22 employs the code word constructed by the cord word S16 fed from the coding section 16 and the check symbol stored in the storing section 20 (the code word consisting of the secret information, the individual characteristic information, the padding data, and the check symbol) as the object. The error correcting section 22 executes the publicly known RS decoding algorithm, i.e., the algorithm containing a process of calculating an error syndrome, a process of calculating an error position, and a process of performing an error correction. The error correcting section 22 operates only when the secret information is reproduced.

The error correcting section 22 calculating the information word that was subjected to the error correction, by executing the RS decoding algorithm. Also, the error correcting section 22 extracts the secret information SD_OUT from the concerned information word. The secret information SD_OUT is sent to the displaying section 12 and is displayed thereon.

[Operation of Secret Information Processing Device 1]

Next, an operation of the secret information processing device 1 of the present embodiment will be explained hereunder, while classifying the operation into (1) an operation in registering the secret information, and (2) an operation in reproducing the secret information.

(1) Operation in Registering Secret Information

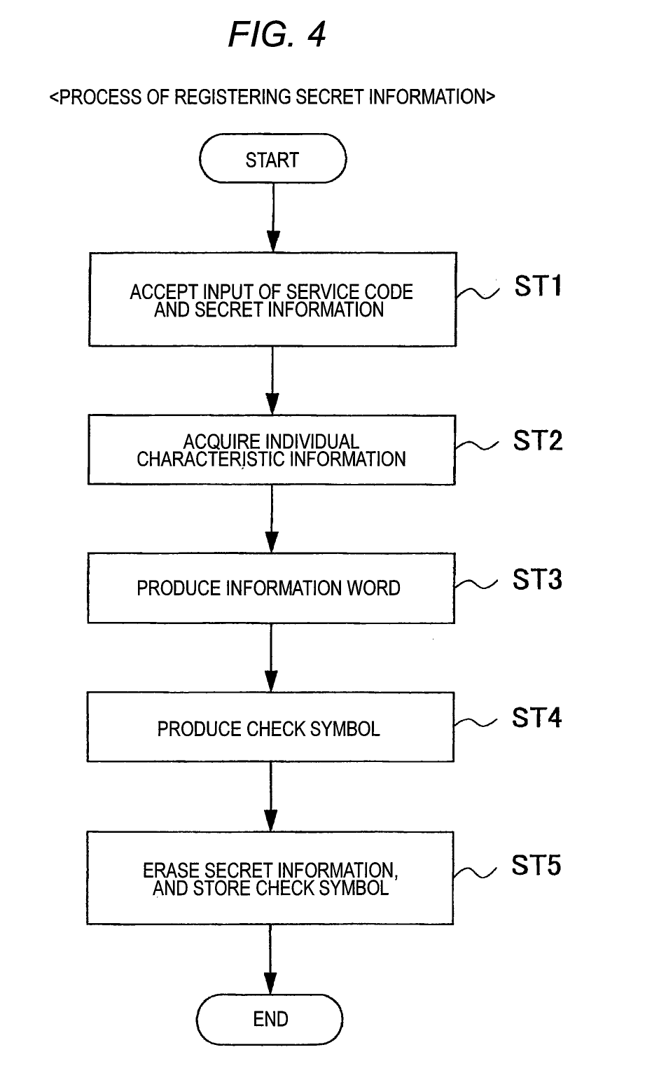

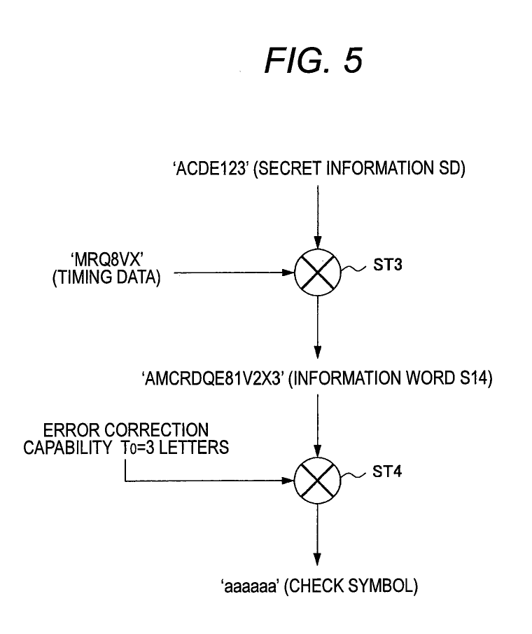

First, the operation in registering the secret information will be explained with reference to FIG. 1, FIG. 4 and FIG. 5 hereunder. FIG. 4 is a flowchart showing the process in registering the secret information. FIG. 5 is a sequence diagram showing a concrete example of data production, in the process in registering the secret information. In this secret information processing device 1, in order to reproduce exactly the secret information, the registering operation explained hereunder must be executed in advance based on the correct secret information (first string information).

First, the user interface 10 accepts the service code indicating the particular service, and the correct secret information SD (first string information) in response to the inputting operation of the user, while correlating them with each other (step ST1). The string data S10 is fed successively to the data processing section 14 as the correct secret information. As explained by reference to FIG. 2, the data processing section 14 acquires the timing data between the strings of the string data S10 as the individual characteristic information (step ST2). Also, the data processing section 14 produces the information word S14 by synthesizing the string data S10 (=secret information SD) and the acquired timing data (=individual characteristic information)(step ST3).

In FIG. 5, an example of the case where ‘ACDE123’ is accepted as the secret information and ‘MRQ8VX’ is acquired as the timing data is illustrated. In this case, as an example of the process in step ST3, ‘AMCRDQE81V2X3 ’ is produced as the information word S14 by synthesizing alternately respective strings of the secret information and the timing data (step ST3).

Then, the coding section 16 produces the 247-byte information word by supplementing the data in the information word S14 such that the coding can be applied by the RS (255, 247;4). Then, the coding section 16 produces the check symbol H based on a previously set error correction capability t0 in the course of coding the 247-byte information word (step ST4).

In an example shown in FIG. 5, when the error correction capability t0 is 3 letters, ‘aaaaaa’ is produced as the check symbol.

When the check symbol is produced by the above operation, the storing section 20 stores the check symbol while correlating it with the service code that is accepted in step ST1, but erases the string data S10 (correct secret information SD) (step ST5).

Therefore, in the secret information processing device 1, the correct secret information itself does not remain in the inside once the registration of the secret information is completed, so that the secret information can be held substantially safely.

(2) Operation in Reproducing Secret Information

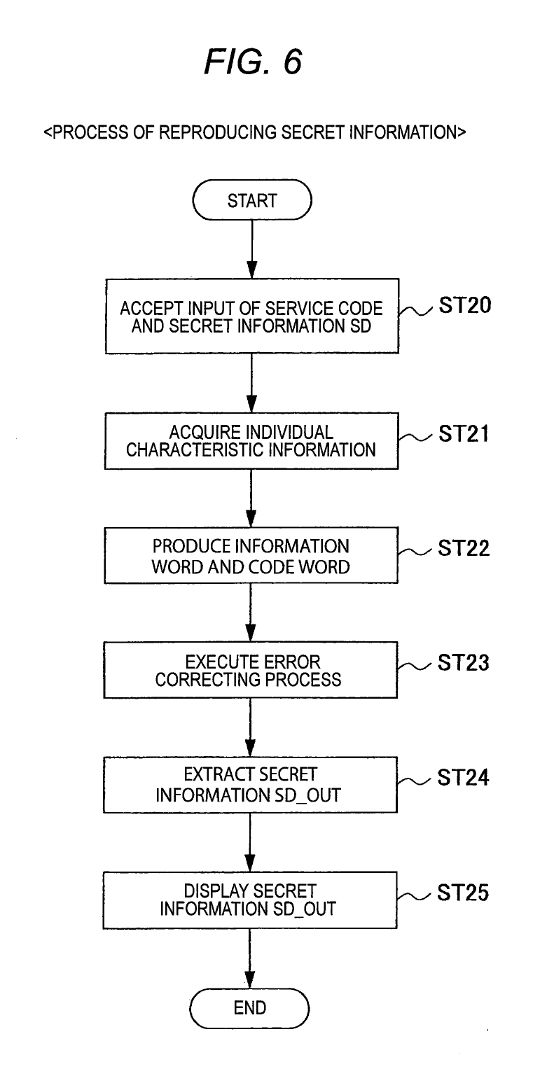

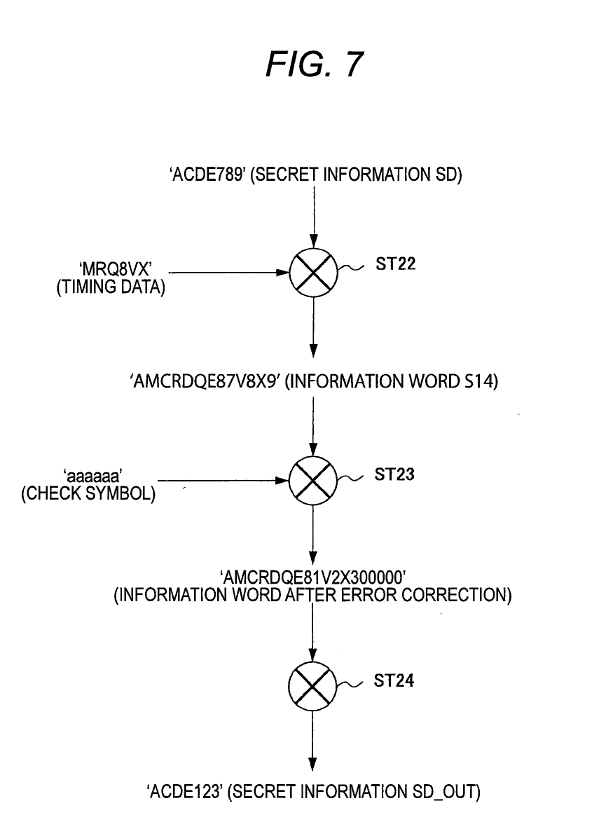

Next, an operation in reproducing the secret information will be explained with reference to the FIG. 1, FIG. 6, and FIG. 7 hereunder. FIG. 6 is a flowchart showing a process in reproducing the secret information. FIG. 7 is a sequence diagram showing a concrete example of data production, in the process in reproducing the secret information. The wording “reproduction of the secret information” means that, when the wrong secret information is input with respect to the particular service, the correct secret information should be produced (reproduced) based on such input.

First, the user interface 10 accepts the service code indicating the particular service and the wrong secret information SD (second string information) in answer to the inputting operation of the user, while correlating them with each other (step ST20). The string data S10 is supplied successively as the wrong secret information SD to the data processing section 14. Then, like the registering operation, the data processing section 14 acquires the timing data between the strings of the string data S10 as the individual characteristic information (step ST21). Then, the data processing section 14 also produces the information word S14 by synthesizing the string data S10 (=secret information SD) and the acquired timing data (=individual characteristic information)(step ST22).

In FIG. 7, an example of the case where ‘ACDE789’ (i.e., the data in which last three letters are wrong) is accepted as the wrong secret information, and ‘MRQ8VX’ is acquired as the timing data is illustrated. Since the timing data is the individual characteristic information, the same data (the same data as that in registering the secret information) is employed irrespective of the right or wrong of the secret information. In the process in step ST22 in this case, like the registering operation, ‘AMCRDQE87V8X9 ’ is produced as the information word S14 by synthesizing alternately respective strings of the secret information and the timing data.

The coding section 16 produces the 247-byte information word by supplementing the data in the information word S14 such that the coding can be applied by the RS (255, 247;4). Then, the coding section 16 produces the coding word S16 (second coding word) by coding the 247-byte information word (step ST22). Then, the error correcting section 22 applies the error correcting process to the coding section that is composed of the coding word S16 supplied from the coding section 16 and the check symbol stored in the storing section 20 (the information word consisting of the secret information, the individual characteristic information, the padding data, and the check symbol) as the object (step ST23). The error correcting section 22 calculates the information word in which the error is corrected by executing this error correcting process, and extracts the secret information SD_OUT from the concerned information word.

As the result of the error correcting process by the error correcting section 22, when the error of the secret information SD accepted in step ST20 is less than the error correcting capability, the error correction is adequately applied to the secret information SD. The error correcting section 22 removes the padding data and the check symbol and separates the secret information from the individual characteristic information, and thus extracts the correct secret information SD_OUT from the information word derived as the result of the error correction (step ST24). The secret information SD_OUT is sent to the displaying section 12 to display thereon (step ST25).

In an example shown in FIG. 7, the error correcting process using a check symbol ‘aaaaaa’ is applied to ‘AMCRDQE87V8X9’ as the information word S14 (step ST23). As a result, as the information word with the padding data and the check symbol, ‘AMCRDQE81V2X300000’ is obtained. Also, ‘ACDE123’ is extracted as the correct secret information SD_OUT by the process in step ST24.

As explained above, in the secret information processing device 1 of the present embodiment, the secret information itself is not stored in registering the secret information, but only the check symbol is stored. Therefore, the secret information can be held substantially safely.

Also, in the secret information processing device 1, in registering the secret information, the check symbol is produced based on the information that is obtained by synthesizing not only the secret information but also the individual characteristic information. As a result, when the person except the regular user inputs the correct secret information in reproducing the secret information, the input individual characteristic information is different from that of the regular user, and thus the secret information is not correctly produced. That is, the secret information processing device 1 has a great effect of preventing the so-called “fake”.

Also, the secret information processing device 1 focuses on such a respect that the inputting pattern of the string through the inputting means are different every user, and thus the input interval between respective strings of the secret information is acquired as the individual characteristic information. That is, the individual characteristic information is acquired in registering the secret information while the regular user is unconscious of such information, so that there is no necessity to input the individual characteristic information separately from the secret information. Therefore, the regular user is not required to store and input the separate information from the secret information, in reproducing correctly the secret information. As a result, such a burden of the regular user can be lessened that the user has to store the information except the essential secret information.

Here, in the secret information processing device of the first embodiment, the individual characteristic information is the timing data between the strings of the input secret information. But the individual characteristic information is not limited to this data.

For example, in case the inputting means for inputting the secret information is a ten-key of the mobile terminal, for example, a plurality of strings are allocated to each key (the strings of ‘2 ’, ‘a’, ‘b’, ‘c’, for example, are allocated to the same key). In such case, the individual characteristic information may be acquired based on the number of times of the operation applied to each key. In the ten-key of the mobile terminal, it may be considered that the number of times of the operation applied to the key when a desired string is chosen by the key operation indicates the private attribute.

Also, when the inputting means for inputting the secret information (the keyboard, or the like) contains the key such as a return key, a space key, a control key, or the like, to which the code used to invalidate the input of the secret information is allocated, the individual characteristic information may be produced based on the code that is input together with the secret information. Also, it may be considered that such code input information indicates the private attribute.

Also, when the inputting means for inputting the secret information chooses the string, which is allocated to the key on the software keyboard (keyboard being implemented by the software) displayed on the displaying section 12, by the choosing operation using the wand-type device or the pointing-type device, for example, the individual characteristic information may be acquired based on a locus of the device that is operated to choose the key.

Accordingly, in the situation that the inputting means such as the wand-type device or the pointing-type device, which is hard to maintain or reproduce a predetermined operation, is employed, the correct secret information can be produced by calibrating a discrepancy of pointing from an input locus of the user based on the error correcting process unless the input locus should be precisely stored and reproduced. Also, unless the secret information should be precisely stored, the correct secret information can be reproduced by storing the input locus.

Also, for example, in inputting the string by using the software keyboard, the auxiliary usage for correcting the wrong string into the right string can be applied by correcting an inputting error.

In this case, in the carrying-out modes of the specification of this application containing the present embodiment, the displaying section 12 is contained in the secret information processing device 1 or a secret information processing device 2. In this case, the displaying section 12 should not always be built in the secret information processing device 1 or the secret information processing device 2. As a result, even when the displaying section 12 is provided outside the secret information processing device 1 or the secret information processing device 2, the similar advantages to those of the invention set forth in the carrying-out modes of the specification of this application containing the present embodiment.

### Second Embodiment

A second embodiment of the secret information processing device 2 of the present invention will be explained hereunder.

The secret information processing device of the present embodiment intends to enhance the exactness of production of the correct secret information, i.e., enhance a resistance to the “fake”, in reproducing the secret information, in addition to the object of the first embodiment. In the present embodiment, like the first embodiment, an explanation will be made by taking a processing system used to process the secret information as an example hereunder. But the present invention is not limited to this embodiment. It is needless to say that the present invention can be applied to the information terminal that employs the string information containing alphanumeric characters, kana and kanji characters, symbols, etc. and signal trains as an input object.

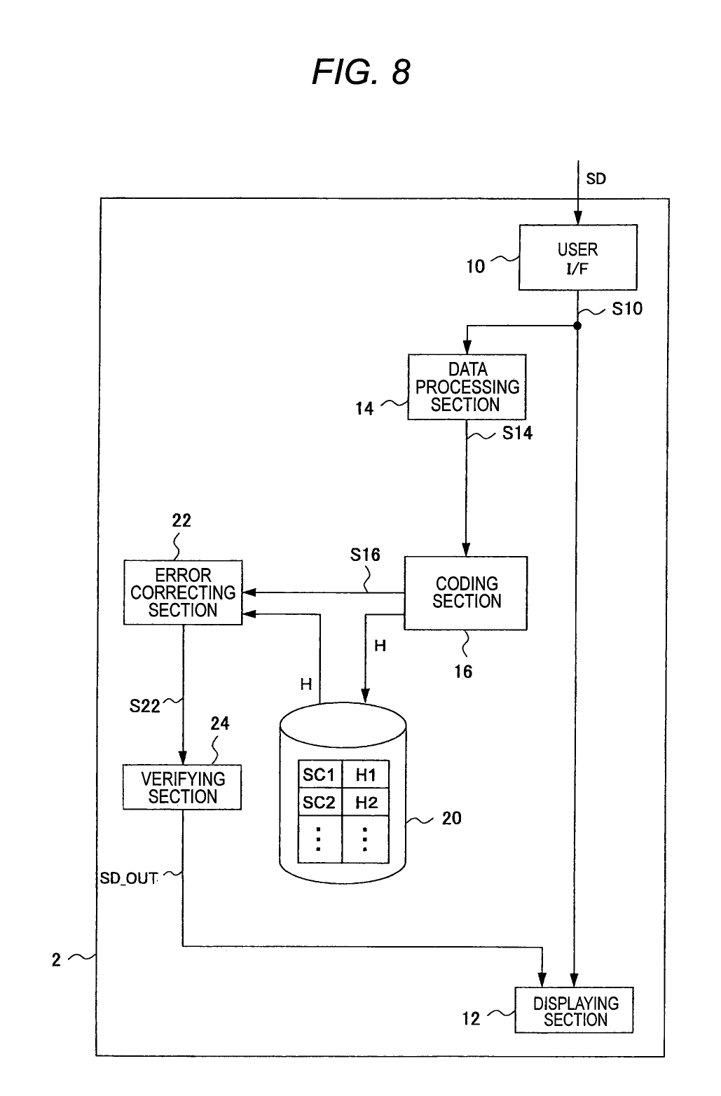

A configuration of a secret information processing device of a second embodiment of the present invention will be explained with reference to FIG. 8 hereunder. FIG. 8 is a block diagram showing a configuration of the secret information processing device 2 of the present embodiment. Here, the same reference symbols are affixed to the same sections of the secret information processing device 1 shown in FIG. 1, and their redundant explanation will be omitted herein.

As shown in FIG. 8, the secret information processing device 2 of the present embodiment is different from the secret information processing device 1 in that a verifying section 24 is provided. The verifying section 24 employs an information word S22 produced by the error correcting section 22 (an information word consisting of the secret information, the individual characteristic information, the padding data, and the check symbol) as the object. The verifying section 24 executes a predetermined verifying process described later, and extracts secret information SD_OUT from the information word S22 and sends this secret information to the displaying section 12 only when the information word S22 is adequate as the correct secret information.

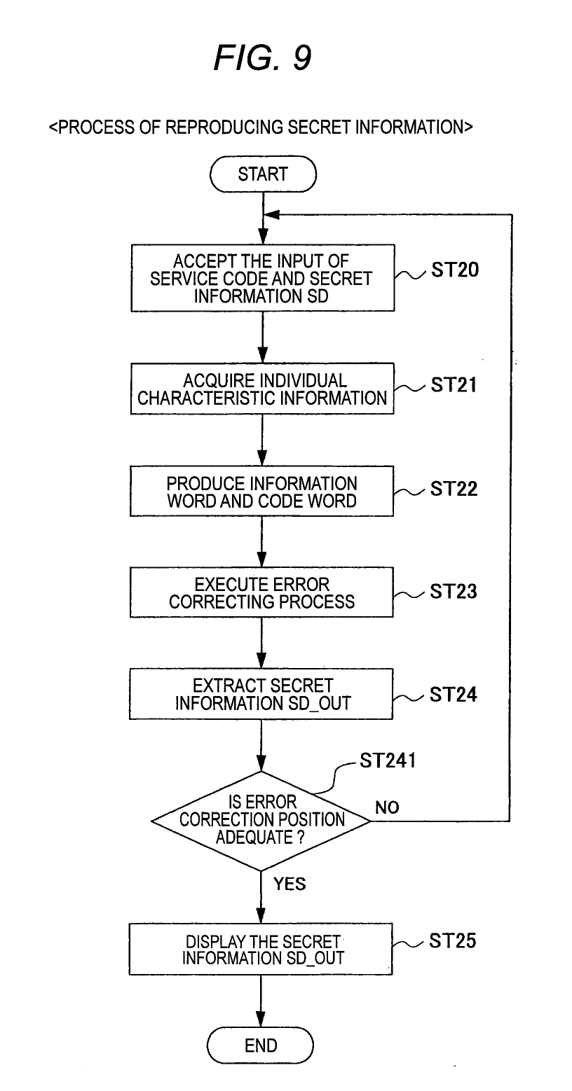

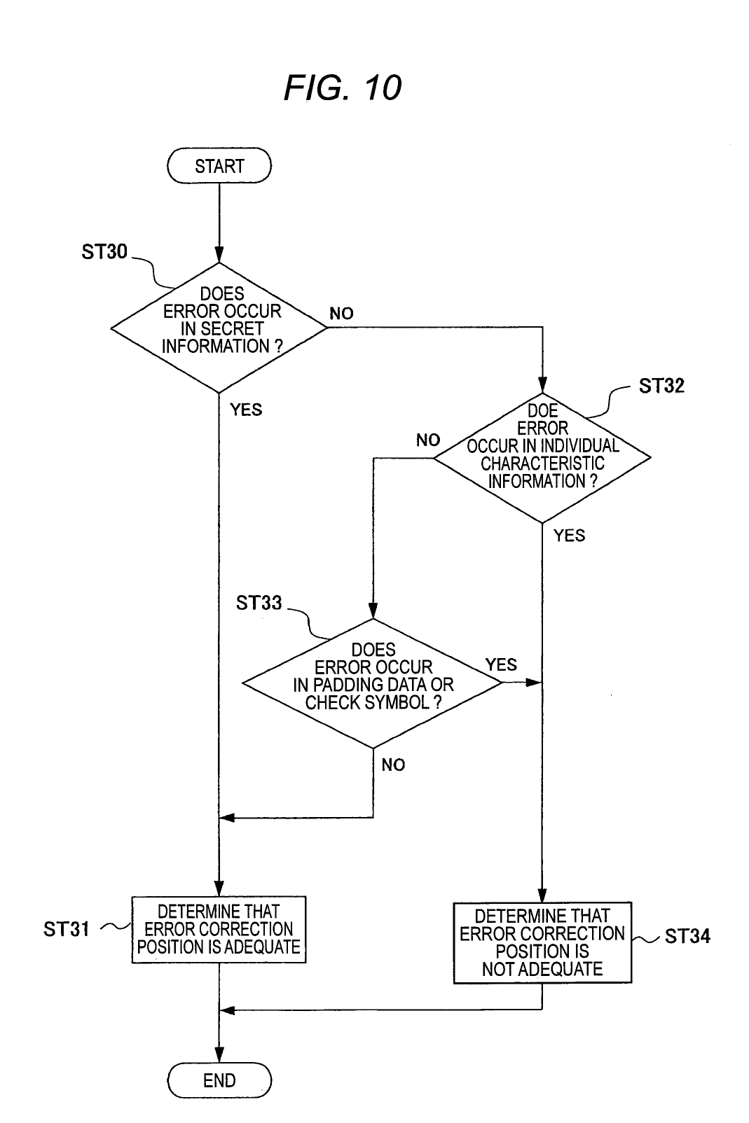

In the secret information processing device 2 of the present embodiment, the process of registering the secret information is similar to that in FIG. 4 and therefore is omitted herein, and a process of reproducing the secret information will be explained with reference to FIG. 9 and FIG. 10 hereunder. FIG. 9 is a flowchart showing the process of reproducing the secret information. FIG. 10 is a flowchart showing a process of verifying the secret information, which is executed by the verifying section 24.

The flowchart shown in FIG. 9 is different from the flowchart already explained and shown in FIG. 6 only in that step ST241 is added. In this step ST241, the verifying section 24 determines as the verifying process whether or not an error correction position is adequate, based on the information word S22 produced by the error correcting section 22 (the information word consisting of the secret information, the individual characteristic information, the padding data, and the check symbol). The flowchart used to determine whether or not the error correction position is adequate is shown in FIG. 10.

That is as shown in FIG. 10, in step ST241, if an error occurs in a part of the string indicating the secret information in the information word S22 (YES in step ST30), the verifying section 24 determines that an error correction position is adequate (step ST31). If no error occurs in a part of the string indicating the secret information (NO in step ST30), the process goes to step ST32. In step ST32 if an error occurs in a part of the string indicating the individual characteristic information in the information word S22 (YES in step ST32), the verifying section 24 determines that an error correction position is not adequate (step ST34). Also, in step ST32, if an error occurs in a part of the string indicating the padding data or the check symbol in the information word S22 (YES in step ST33), the verifying section 24 determines that an error correction position is not adequate (step ST34). Also, if not (NO in step ST33), the verifying section 24 determines that the error correction position is adequate (step ST31). In this manner, when the error correcting position occurs only in the string indicating the secret information, it is determined that the individual characteristic information does not contain the error. Therefore, it can be determined that the error in the secret information is caused due to the inputting error of the secret information or lapse of memory of the secret information by the regular user. That is, the resistance to the “fake” can be enhanced by this verifying process.

In FIG. 9 and FIG. 10, the secret information produced substantially by the error correcting section 22 is verified depending on whether or not the error correction position is adequate. But the verification of the secret information can be made by the method except this method. Variations, in which only the verification processing method is different, in the secret information processing device 2 of the second embodiment will be explained hereunder.

<Variation 1>

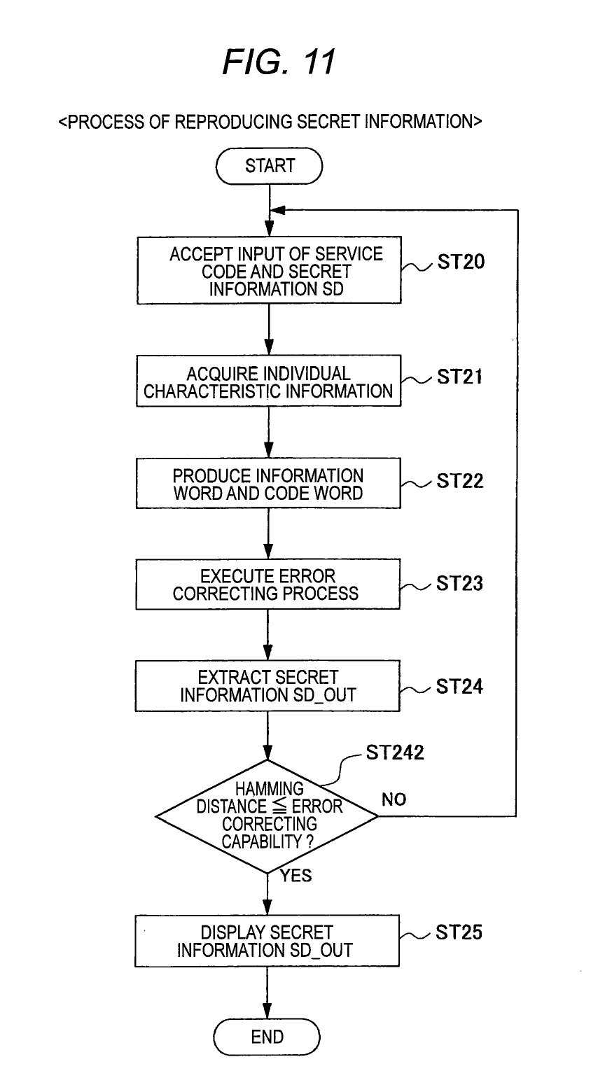

FIG. 11 is a flowchart showing a process of reproducing the secret information containing another example of the process of verifying the secret information. The flowchart shown in FIG. 11 is different from the flowchart shown in FIG. 9 in that a process in step ST242 is executed instead of step ST241.

In step ST242 in the flowchart shown in FIG. 11, the verifying section 24 made the verification of the secret information produced by the error correcting section 22 by comparing the Hamming distance obtained as the result of the error correcting section 22 with a previously set error correcting capability. That is, in step ST242, the verifying section 24 determines that the secret information obtained by the error correcting process is correct when the Hamming distance is equal to or smaller than the error correcting capability. Then, the process goes to step ST25.

According to the verifying process in step ST242, the correct secret information can be produced and displayed in response to the set error correcting capability as far as a part of the input secret information coincides with a part of the correct secret information. In other words, such a situation can be prevented that the secret information is produced and displayed in response to the input that is largely different from the correct secret information. Therefore, the resistance to the “fake” can be enhanced by this verifying process.

<Variation 2>

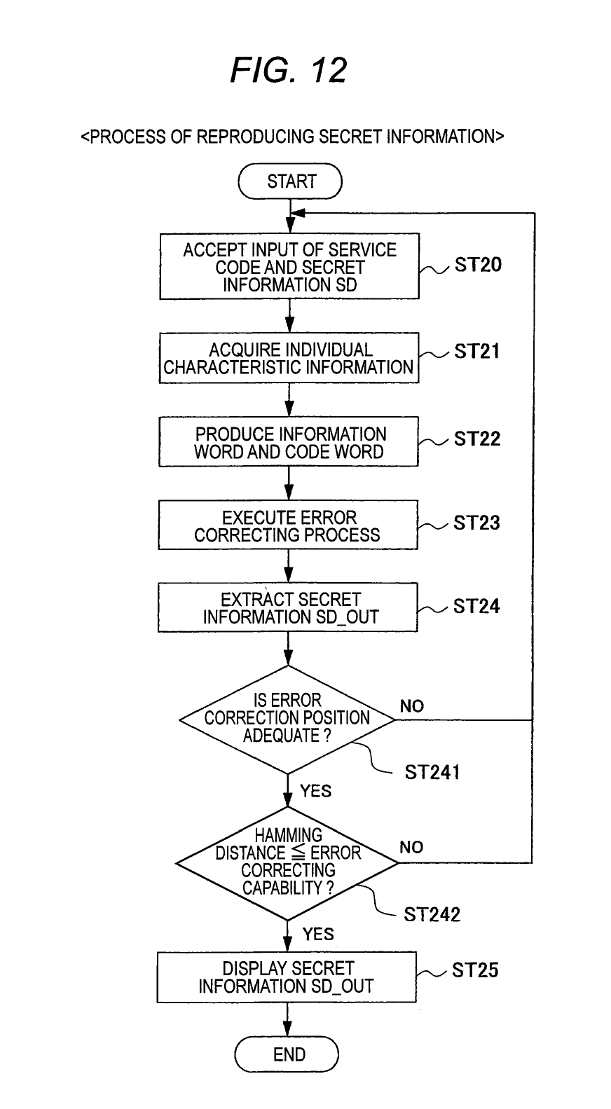

As shown in FIG. 12, the resistance to the “fake” can be further enhanced by applying the process in step ST241 in FIG. 9 and the process in step ST242 in FIG. 11 in combination.

<Variation 3>

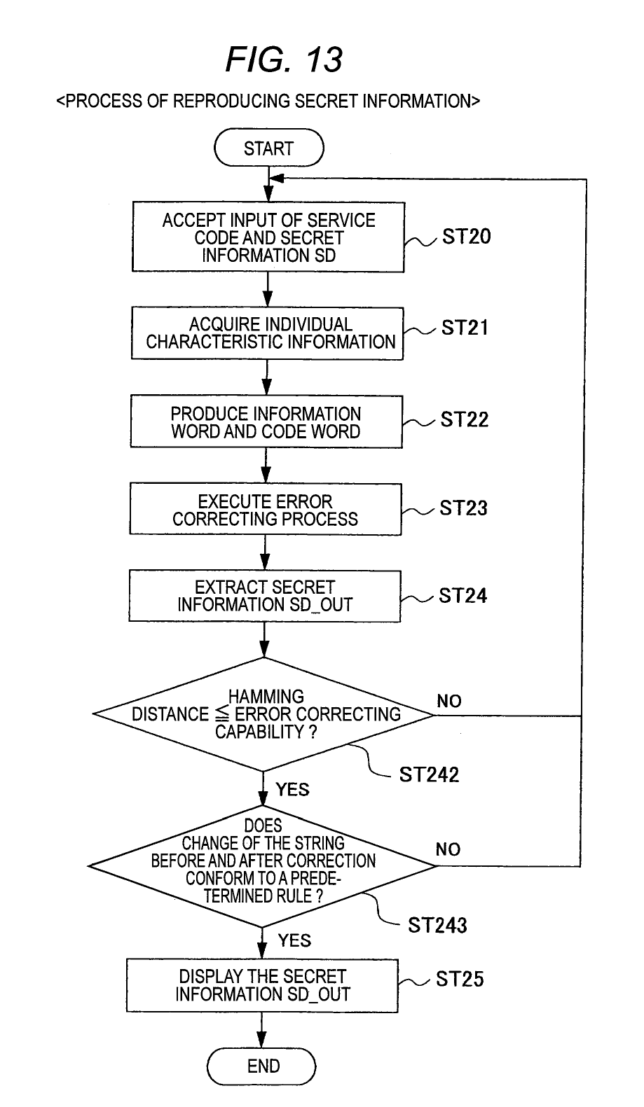

FIG. 13 is a flowchart showing a process of reproducing the secret information containing yet still another example of a process of verifying the secret information. The flowchart shown in FIG. 13 is different from the flowchart shown in FIG. 11 in that a process in step ST243 is added. In step ST243 the verifying section 24 determines whether or not a change of the string of the secret information conforms to a predetermined rule before and after the error correcting process executed by the error correcting section 22. If the change conforms to a predetermined rule (YES in step ST243), the verifying section 24 goes to step ST25.

The verifying section 24 can determine whether or not a change of the string of the secret information conforms to a predetermined rule before and after the error correcting process, based on the physical mode of the inputting means such as the keyboard, or the like. For example, such a case is assumed that the secret information processing device 2 of the present embodiment is installed into the mobile terminal and, in the key arrangement of the mobile terminal, the strings ‘2’, ‘5’, ‘8’ are allocated to the same keys, to which the strings ‘A’, ‘J’, ‘T’ are allocated, respectively in response to the setting in the input mode. In this case, when such a situation is caused that the strings ‘A’, ‘J’, ‘T’ of a part of the secret information that underwent the error correction by the error correcting section 22 respectively are given to the strings ‘2’, ‘5’, ‘8’ of a part of the secret information being input through the user interface 10 (e.g., before the error correction: ‘ACDE123’, after the error correction: ‘2CDE123’), this situation can be considered as the inputting error of the secret information caused by the regular user due to the setting error in the input mode. At this time, the verifying section 24 determines that a change of the string of the secret information conforms to a predetermined rule, and causes the displaying section 12 to display the secret information after the error correction.

In the above example of the mobile terminal, in step ST243, the decision about whether or not a change of the string of the secret information conforms to a predetermined rule is made based on such a premise that the strings before and after the error correction are allocated to the same keys. For example, in step ST243, when the keyboard in JIS arrangement, or the like is prepared as the inputting means, such decision can be made based on such a premise that the strings before and after the error correction are located in adjacent positions on the key arrangement. For example, in the keyboard in JIS arrangement, the strings ‘T’, ‘J’, ‘I’ are located adjacently to ‘R’, ‘H’, ‘U’ respectively. When such a situation is caused that the strings ‘R’, ‘H’, ‘U’ of a part of the secret information that underwent the error correction by the error correcting section 22 respectively are given to the strings ‘T’, ‘J’, ‘I’ of a part of the secret information being input through the user interface 10 (e.g., before the error correction: ‘ACDT123’, after the error correction: ‘ACDR123’), this situation can be considered as the inputting error of the secret information caused by the regular user due to the displacement of the input position. At this time, the verifying section 24 determines that a change of the string of the secret information has a correlation based on a predetermined rule, and causes the displaying section 12 display the secret information after the error correction.

In step ST243, the decision about whether or not a change of the string of the secret information conforms to a predetermined rule can be made based on such a premise that the strings before and after the error correction have a relation between the uppercase letter and the lowercase letter.

In this manner, the verifying process to determine whether or not a change of the string of the secret information conforms to a predetermined rule is provided before and after the error correcting process. Therefore, the resistance to the “fake” can be enhanced by this verifying process.

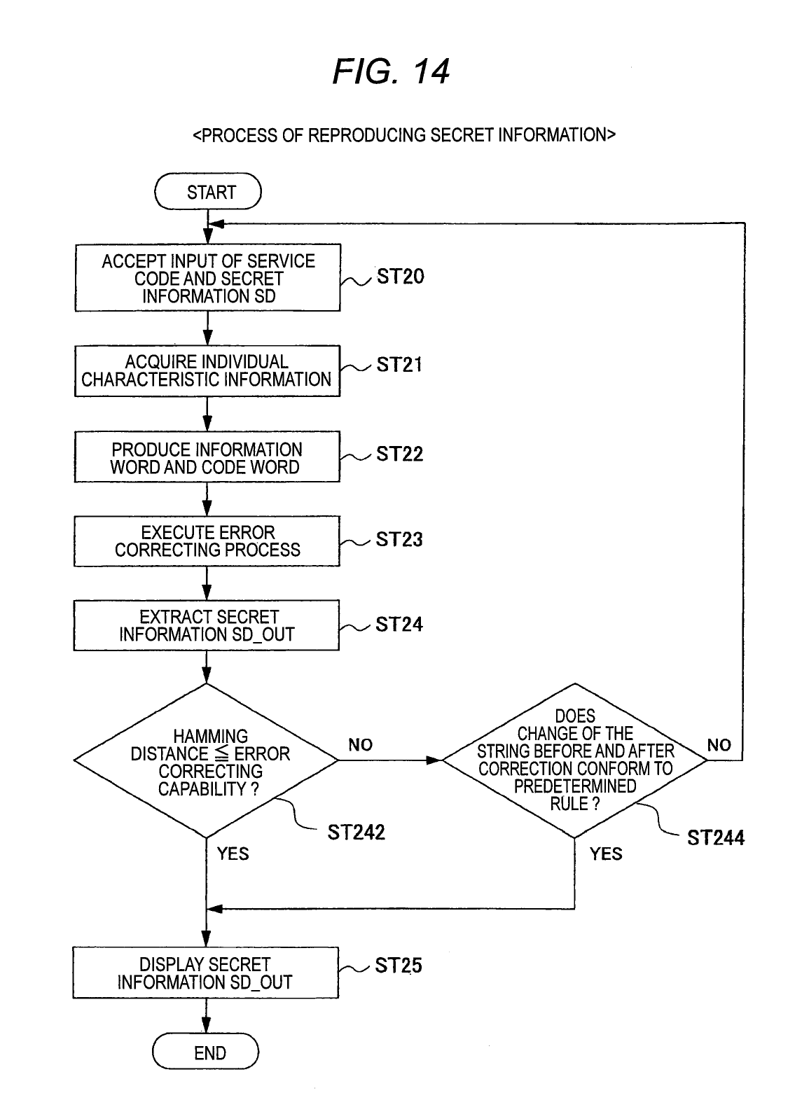

Here, the flowchart shown in FIG. 13 can be varied as shown in FIG. 14. A process in step ST244 in FIG. 14 is the same as the process in step ST243 in FIG. 13. In the process of reproducing the secret information shown in FIG. 14, if a change of the string of the secret information conforms to a predetermined rule (YES in step ST244) even when the verifying process shown in step ST242 (the verifying process based upon the Hamming distance) is not satisfied (NO in step ST242), the process goes to step ST25. Accordingly, such a situation can be prevented that the correct secret information is not displayed due to the simple inputting error of the regular user.

As explained above, according to the secret information processing device 2 of the present embodiment, the verifying process is applied to the secret information obtained by the error correcting process in reproducing the secret information. Therefore, the resistance to the “fake” can be enhanced in contrast to the first embodiment.

With the above, the embodiments of the present invention are described in detail, but the concrete configuration and system are not limited to the present embodiment. A change of design in a scope without departing from a gist of the present invention, an adaptation to other systems, and the like may be included.

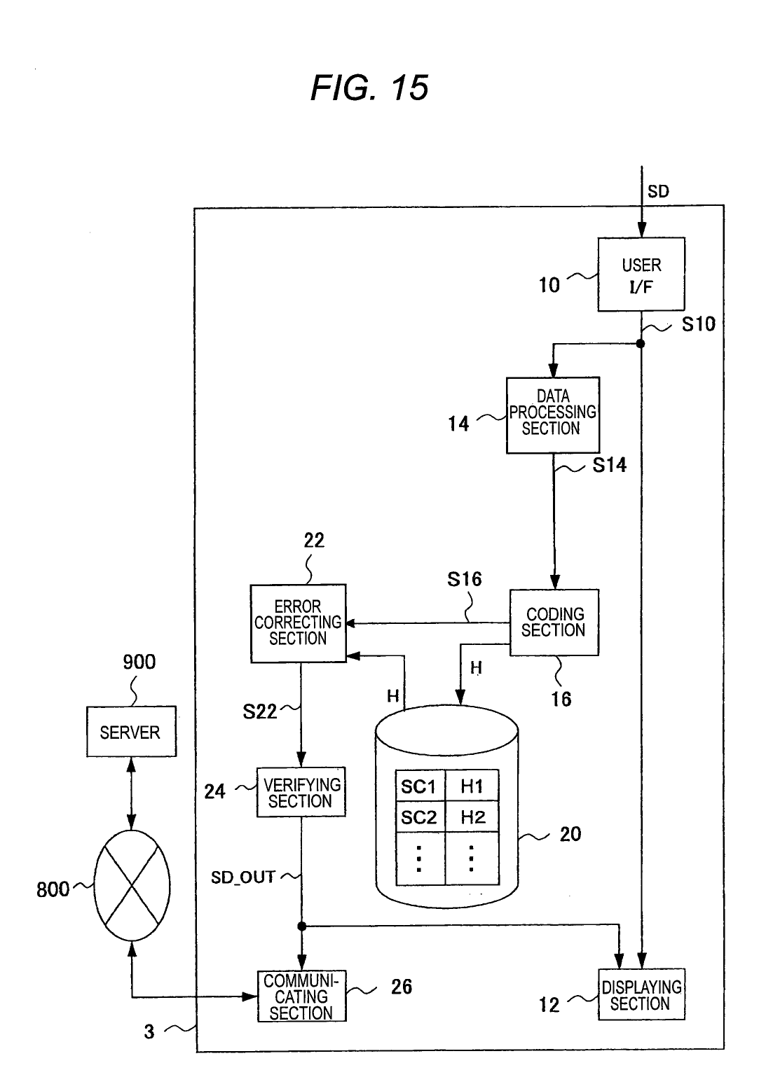

For example, FIG. 15 is a block diagram showing a configuration when the secret information processing device of each embodiment is installed into the mobile terminal. A mobile terminal 3 is equipped with a communicating section 26 that holds communication with an external server 900 via a network 800. The mobile terminal 3 is constructed such that only the secret information SD_OUT verified by the verifying section 24 is sent to the server 900 to provide the particular service via the network 800.

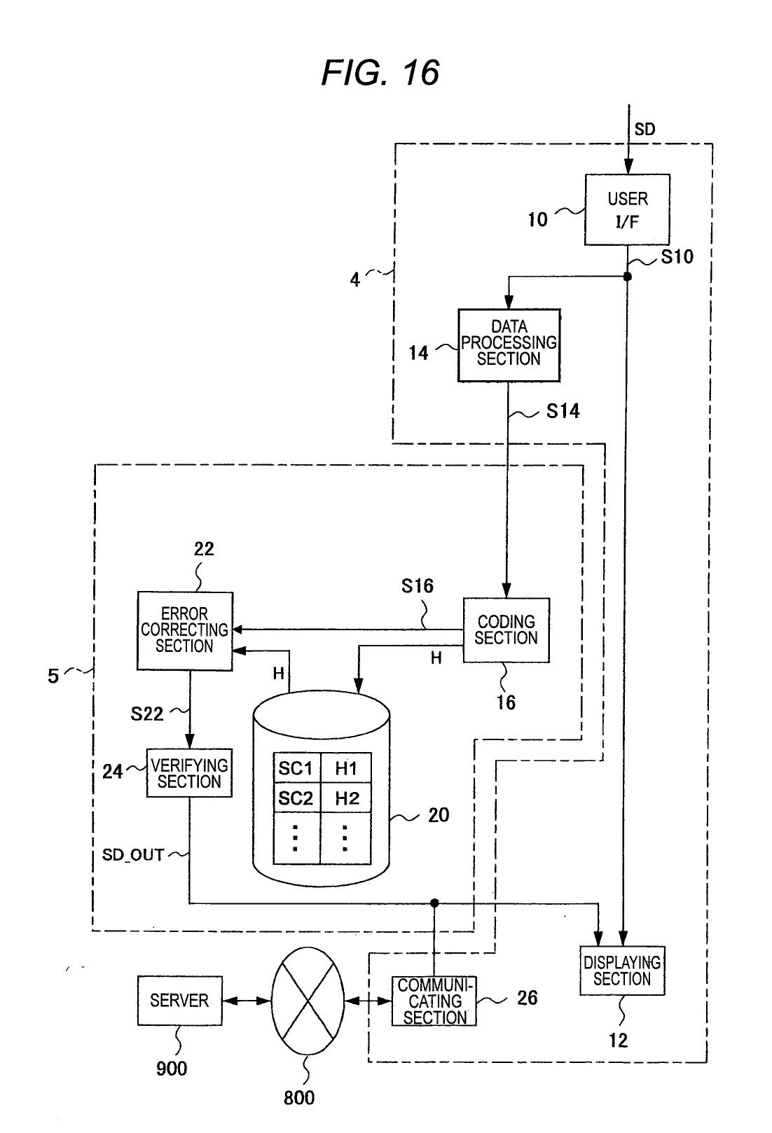

Also, FIG. 16 is a block diagram showing a configuration when respective sections of the secret information processing device of each embodiment are separated into a mobile terminal and a card type module and are installed. A card type module 5 is fitted to a mobile terminal 4 when the user receives the provision of the particular service in answer to the authentication given by the secret information. The mobile terminal 4 is similar to the mobile terminal 3 in that only the secret information SD_OUT verified by the verifying section 24 is sent to the server 900 to provide the particular service via the network 800.

Also, an object of the present invention can be implemented by a program that causes a computer to execute a series of procedures that are equivalent functionally to the operation of the secret information processing devices in respective embodiments. Also, it is needless to say that an object of the present invention can be implemented when a recording medium (or a recording medium) on which the program code is recorded is supplied to the system or the equipment, and the computer (or CPU or MPU) of the system or the equipment reads and executes the program code stored in the recording medium. In this case, the program code itself being read from the recording medium implements the function of the foregoing embodiments, and the recording medium on which the program code is stored constitutes the present invention. Also, it is needless to say that such a case should be contained in a scope of the present invention that not only the functions of the above embodiments are implemented by executing the program code that the computer reads, but also the functions of the above embodiments are implemented by a part or all of the actual processes that the operating system (OS), which is working on the computer, or the like, executes based on the instruction of the program code.

The present invention is explained in detail with reference to the particular embodiments. But it is obvious for those skilled in the art that various variations and modifications can be applied without departing from a spirit and a scope of the present invention.

This application is based upon Japanese Patent Application (Patent Application No. 2007-060043) filed on Mar. 9, 2007; the contents of which are incorporated herein by reference.

### INDUSTRIAL APPLICABILITY

The secret information processing device according to the present invention can hold safely the string information and also lessen the user's burden of storing the information relating to the string information and correcting the inputting error, and therefore is useful as the information processing terminal for the computer, the mobile terminal, the authentication terminal, their inputting device, and the like.

1. An information processing device, comprising:
an information inputting section that inputs string information in response to a user's operation;
an information acquiring section that acquires individual characteristic information of a user based on the user's operation;
a coding section that produces a first code word, which is a cord word obtained by synthesizing a correct first string information being input by the information inputting section and the individual characteristic information under a predetermined rule, in registering the string information;
a storing section that stores a check symbol for error correction being produced based on the first code word after the string information is registered; and
an error correcting section that applies the error correction using the check symbol stored in the storing section to a second cord word, which is produced by the coding section based on second string information being input by the information inputting section and the individual characteristic information, when the string information is reproduced.

2. The information processing device according to claim 1, further comprising:
an error correction verifying section that determines that the first string information is reproduced correctly by the error correcting section when a Hamming distance obtained by the error correcting section is equal to or smaller than an error correcting capability for the error correction.

3. The information processing device according to claim 1, further comprising:
an error correction verifying section that determines that the first string information is reproduced correctly by the error correcting section when an error correcting position obtained by the error correcting section is located in the second string information.

4. The information processing device according to claim 1, further comprising:
an error correction verifying section that determines that the first string information is reproduced correctly by the error correcting section when a Hamming distance obtained by the error correcting section is equal to or smaller than an error correcting capability for the error correction and an error correcting position obtained by the error correcting section is located in the second string information.

5. The information processing device according to claim 1, wherein the information inputting section inputs the string information via a plurality of keys which are used as an object of the user's operation, to which a string is allocated respectively, and which are aligned in a predetermined pattern, and
further comprising:
an error correction verifying section that determines that the first string information is reproduced correctly by the error correcting section when a change of string in the first string information and the second string information conforms to a predetermined rule that is defined based on alignment positions of the plurality of keys.

6. The information processing device according to claim 1, wherein the information inputting section inputs the string information via a plurality of keys which are used as an object of the user's operation and to which a string is allocated respectively; and
wherein the individual characteristic information is produced based on an input interval with respect to respective keys of the plurality of keys when the string information is input.

7. The information processing device according to claim 1, wherein the information inputting section inputs the string information via a plurality of keys which are used as an object of the user's operation, to which a string is allocated respectively, and from which one string is chosen sequentially as an input candidate from a plurality of strings that are allocated to a predetermined key in response to one of plural operations applied to the predetermined key; and
wherein the individual characteristic information is produced based on a number of operating times with respect to each key when the string information is input.

8. The information processing device according to claim 1, wherein the information inputting section inputs the string information via a plurality of keys which are used as an object of the user's operation, and to which one or plural strings used to validate an input as the string information and one or plural codes used to invalidate the input as the string information are allocated respectively; and
wherein the individual characteristic information is produced based on the code which is input together with the string information.

9. The information processing device according to claim 1, wherein the information inputting section inputs the string information via a choosing operation by a wand-type device or a pointing-type device with respect to a plurality of keys which are implemented by a software, to which a string is allocated respectively, and which are aligned in a predetermined pattern; and
wherein the individual characteristic information is produced based on a locus of the wand-type device or the pointing-type device used in the choosing operation.

10. A method of correcting an error, comprising:
procedures in registering string information, including:
a procedure of inputting correct first string information in response to a user's operation;
a procedure of acquiring first individual characteristic information of a user based on an input of the first string information;
a procedure of producing a first code word by synthesizing the first string information and the first individual characteristic information under a predetermined rule; and
a procedure of erasing the first string information, and storing a check symbol obtained in a course of production of the first code word; and
procedures in reproducing the string information, including:
a procedure of inputting second string information in response to a user's operation;
a procedure of acquiring second individual characteristic information of the user based on an input of the second string information;
a procedure of producing a second code word by synthesizing the second string information and the second individual characteristic information under the predetermined rule; and
a procedure of applying an error correction using the stored check symbol to the second code word as an object.

11. A computer-readable recording medium for storing a program for causing a computer to execute the method set forth in claim 10.
